(19) United States
(12) Patent Application Publication
(10) Pub. No.: US 2017/0179737 A1
(43) Pub. Date: Jun. 22, 2017

(54) BATTERY DRIVEN SYSTEM, BATTERY PACK, AND SEMICONDUCTOR DEVICE

(71) Applicant: Renesas Electronics Corporation, Tokyo (JP)

(72) Inventors: Masaya EMI, Tokyo (JP); Masaki Hogari, Tokyo (JP); Chikara Kobayashi, Tokyo (JP)

(21) Appl. No.: 15/368,308

(22) Filed: Dec. 2, 2016

(30) Foreign Application Priority Data
Dec. 22, 2015 (JP) 2015-249981

(51) Int. Cl. H02J 7/00; G01R 31/36

(52) U.S. Cl. CPC H02J 7/0021; G01R 31/3627; G01R 31/3655; H02J 2007/0001

(57) ABSTRACT

A battery driven system has a secondary battery, a main unit, a switch provided on a power source path or a signal path of the main unit, an impedance measurement circuit, a memory circuit, and an authentication circuit. The impedance measurement circuit measures the impedance of the secondary battery. The memory circuit holds a preset impedance characteristic of the secondary battery as collating data. The authentication circuit compares measurement data based on the measured result of the impedance measurement circuit with the collating data, thereby determining whether the secondary battery is suitable. It controls the switch to be turned off, when the secondary battery is not suitable.

### CROSS-REFERENCE TO RELATED APPLICATIONS

The disclosure of Japanese Patent Application No. 2015-249981 filed on Dec. 22, 2015 including the specification, drawings and abstract is incorporated herein by reference in its entirety.

The present invention relates to a battery driven system, a battery pack, and a semiconductor device, and relates to, for example, a verification technology for the battery pack.

### BACKGROUND

WO 2012/095913 discloses a method of measuring the impedance spectrum of a lithium ion secondary battery having a predetermined frequency range using an impedance measurement device, and evaluating a degradation state of a battery based on coordinates of a vertex of a circular arc-shape part which is obtained at the time the measured result is represented on a complex plane. Japanese Unexamined Patent Application Publication No. 2015-32572 discloses a method of identifying whether a degradation phenomenon of the inside of the lithium ion secondary battery is caused by a positive electrode plate or a negative electrode plate, and analyzing a degradation level of the battery.

### SUMMARY

For example, a secondary battery used for various portable units is degraded by repetitive usage, unlike the main device. Thus, it is necessary to exchange the battery pack with a mounted secondary battery on a regular basis. Thus, the market of selling the battery pack as a single substance has expanded, and this market may expand more than the market of the main device in some case.

In this context, under the present situation, in the market of the battery pack, the counterfeit battery packs have been distributed, and the counterfeit products are very different from the regular products designated by the main device. Quite many of the counterfeit products have poor quality. As a result, the counterfeit products may fearfully not only prevent the sales of the main device's manufacturer, but also damage safety of the battery pack and cause accidents in the market. Supposing that an accident in the market occurs, a significant damage occurs in the main device's manufacturer, regardless of the counterfeit products.

In the above circumstances, it is considered to perform authentication for identifying whether a regular product or counterfeit product, in association with the main device and the battery pack. Some specific authentication methods include a method of reading a predetermined resistance value of a battery pack using the main device and a method of handling an authentication code encrypted by both controllers. These authentication methods are to indirectly secure safety of the secondary battery mounted on the battery pack, by verifying mounted parts of the battery pack. Thus, for example, by simply exchanging only the secondary battery in the battery pack, when the battery pack having the poor-quality secondary battery mounted thereon is distributed, it is difficult to guarantee the safety of the secondary battery.

Preferred embodiments to be described below have been made in consideration of the above, and any other objects and new features will be apparent from the descriptions of the present specification and the accompanying drawings.

A battery driven system according to an embodiment has a secondary battery, a main unit to/from which the secondary battery is attachable/detachable, a switch which is provided on a power source path or a signal path of the main unit, an impedance measurement circuit, a memory circuit, and an authentication circuit. The impedance measurement circuit is coupled to the secondary battery, and measures the impedance of the secondary battery. The memory circuit holds a preset impedance characteristic of the secondary battery as collating data. The authentication circuit compares measurement data based on a measured result of the impedance measurement circuit and the collating data, thereby determining whether the secondary battery is suitable. When it is not suitable, it controls the switch to be OFF.

According to the above one embodiment, it is possible to guarantee the safety of the secondary battery.

### BRIEF DESCRIPTION OF THE DRAWINGS

FIG. 1 is a schematic diagram illustrating a configuration example of the main part in a battery driven system according to an embodiment 1 of the present invention.

FIG. 2 is an explanatory diagram illustrating a schematic operational example of the main part in the battery driven system of FIG. 1.

FIG. 3 is a circuitry diagram illustrating a configuration example of the surroundings of an impedance measurement circuit in the battery pack of FIG. 1, in a battery driven system according to an embodiment 2 of the present invention.

FIG. 4 is a flow diagram showing an example of process contents when the battery pack of FIG. 1 creates measurement data, in the battery driven system according to the embodiment 2 of the present invention.

FIG. 5 is a flow diagram showing an example of process contents when an authentication circuit of the main device of FIG. 1 collates the measurement data, in the battery driven system according to the embodiment 2 of the present invention.

FIG. 6A is a circuitry diagram illustrating an example of an equivalent circuit of a secondary battery in the battery pack of FIG. 3, and FIG. 6B is a characteristic diagram illustrating an example of the characteristics of a Cole-Cole plot.

FIG. 7 is a diagram illustrating a characteristic example of the Cole-Cole plot regarding a secondary battery which is determined as “not suitable”, in the flow of FIG. 5.

FIG. 8 is a circuitry diagram illustrating a configuration example of the surroundings of an impedance measurement circuit in the battery pack of FIG. 1, in a battery driven system according to an embodiment 3 of the present invention.

FIG. 9 is a characteristic diagram illustrating an example of a measured result in the impedance measurement circuit of FIG. 8.

FIG. 10 is a circuitry diagram illustrating another configuration example of the surroundings of the impedance measurement circuit in the battery pack of FIG. 1, in the battery driven system according to the embodiment 3 of the present invention.

FIG. 11 is a schematic diagram illustrating a configuration example of the main part, in a battery driven system according to an embodiment 4 of the present invention.

FIG. 12 is a schematic diagram illustrating a configuration example of a battery driven system applying the system of FIG. 11.

FIG. 13 is a schematic diagram illustrating another configuration example of the battery driven system applying the system of FIG. 11.

FIGS. 14A and 14B are schematic diagrams each illustrating a configuration example of the main part, in a battery driven system which has been examined as a comparative example of the present invention.

### DETAILED DESCRIPTION

In the following preferred embodiments, if necessary for convenience sake, descriptions will be made to divided plural sections or preferred embodiments, however, unless otherwise specified, they are not mutually irrelevant, but one is in relations of modifications, details, supplementary explanations of part or whole of the other. Further, in the following preferred embodiments, in the case of reference to the number of an element (including quantity, numeric value, amount, range), unless otherwise specified and/or unless clearly limited in principle, the present invention is not limited to the specified number, and a number over or below the specified one may be used.

In the following preferred embodiments, the constituent elements (including element steps) are not necessarily indispensable, unless otherwise specified and/or unless considered that they are obviously required in principle. Similarly, in the following preferred embodiments, in the reference of the forms of the constituent elements or the positional relationships, they intend to include those approximating or similar substantially to the forms and like, unless otherwise specified and/or unless considered that they are obviously not required in principle. This is also true of the foregoing numerical values (including quantity, numeric value, amount, range).

Descriptions will now specifically be made to the preferred embodiments based on the accompanying drawings. In all of the drawings, the same or related numerals are given to those members having the same functions, and the descriptions thereof will not be made over and over.

### Embodiment 1

### <Schematic Configuration of Battery Driven System>

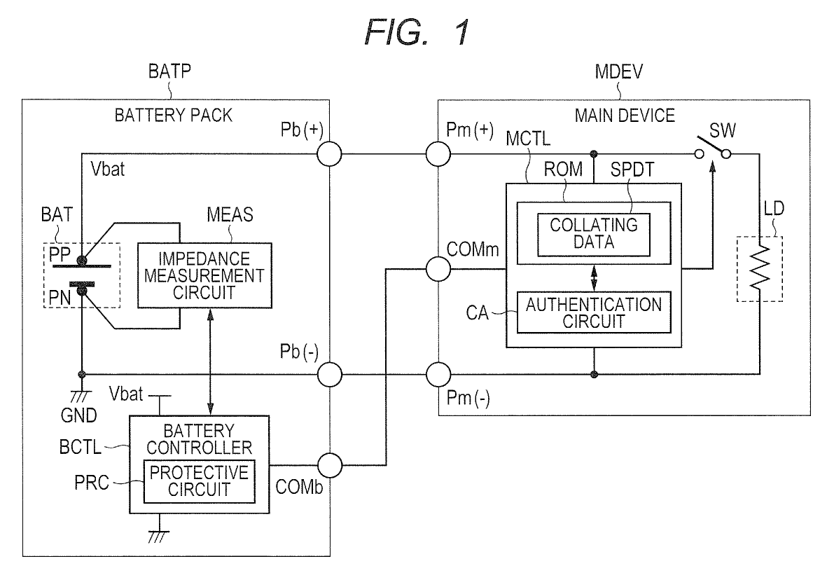

FIG. 1 is a schematic diagram illustrating a configuration example of the main part, in the battery driven system according to an embodiment 1 of the present invention. The battery driven system illustrated in FIG. 1 includes a secondary battery pack BATP and a main device MDEV to/from which the secondary battery pack BATP is attachable/detachable. The secondary battery pack BATP includes power source terminals Pb(+) and Pb(−), a communication terminal COMb, a secondary battery BAT, an impedance measurement circuit MEAS, and a battery controller BCTL.

Though not necessarily limited, the secondary battery BAT is a lithium ion secondary battery, and generates a power source having a predetermined voltage level between a positive electrode PP and a negative electrode PN. In this case, at the positive electrode PP, a source voltage Vbat is generated using a reference source voltage GND coupled to the negative electrode PN, as a reference. The power source terminals Pb(+) and Pb(−) are coupled to the electrodes PP and PN of the secondary battery BAT, and are configured to be attachable/detachable to/from the main device MDEV. The communication terminal COMb is, for example, a serial communication terminal, and communicates with the main device MDEV.

The impedance measurement circuit MEAS is coupled to the secondary battery BAT, and measures the impedance of the secondary battery BAT. Specifically, the impedance measurement circuit MEAS measures at least one of the DC impedance (DC resistance) of the secondary battery BAT, the absolute value of the AC impedance, and the absolute value and phase of the AC impedance (the real part and the imaginary part).

Though not necessarily limited, the battery controller BCTL is a micro controller (MCU: Micro Control Unit). The battery controller BCTL is coupled to the impedance measurement circuit MEAS and the communication terminal COMb, and transmits measurement data based on a measured result of the impedance measurement circuit MEAS from the communication terminal COMb. The battery controller BCTL includes a protective circuit PRC, which determines an overvoltage or an overcurrent of the secondary battery BAT and performs various controlling in accordance with the determined result. Though not illustrated, a power source switch is provided on a power source path of the source voltage Vbat or the reference source voltage GND, and the protective circuit PRC turns off the power source switch in accordance with the determined result.

Normally, the impedance measurement circuit MEAS is configured mainly with an analog circuit, while the battery controller BCTL is configured mainly with a digital circuit. The impedance measurement circuit MEAS and the battery controller BCTL are possibly configured, for example, with one semiconductor chip (semiconductor device) as a SOC (System On a Chip), or configured with one package (semiconductor device) by appropriately wiring the different semiconductor chips.

The main device MDEV includes power source terminals Pm(+) and Pm(−), a communication terminal COMm, a main controller MCTL, a switch SW, and a load unit (main unit) LD. The power source terminals Pm(+) and Pm(−) are coupled to the power source terminals Pb(+) and Pb(−) of the battery pack BATP, and are configured to be attachable/detachable to/from the battery pack BATP. The communication terminal COMm communicates with the battery pack BATP through the communication terminal COMb.

The load unit LD executes a predetermined operation in accordance with the main function of the main device MDEV, using a power source from the secondary BAT, supplied from the power source terminals Pm(+) and Pm(−). When, for example, the main device MDEV is an image processing apparatus, the load unit LD executes image processing. When, for example, it is a wireless communication device, the unit executes various processes necessary for wireless communications. The switch SW is provided on the power source path of the load unit LD, and controls to supply or not to supply power to the load unit LD.

The main controller MCTL is coupled between the power source terminals Pm(+) and Pm(−), and is a micro controller (MCU), though not particularly limited. The main controller MCTL includes a non-volatile memory circuit ROM and an authentication circuit. The memory circuit ROM holds a predetermined impedance characteristic of the secondary battery BAT as collating data SPDT. The authentication circuit CA receives measurement data from the above-described battery controller BCTL through the communication terminal COMm. The authentication circuit CA compares the measurement data and the collating data SPDT, to determine whether the secondary battery BAT is suitable or not. When determined that it is suitable, the switch SW is turned on, whereas, when determined that it is not suitable, the switch SW is turned off.

### <Schematic Operation of Battery Driven System>

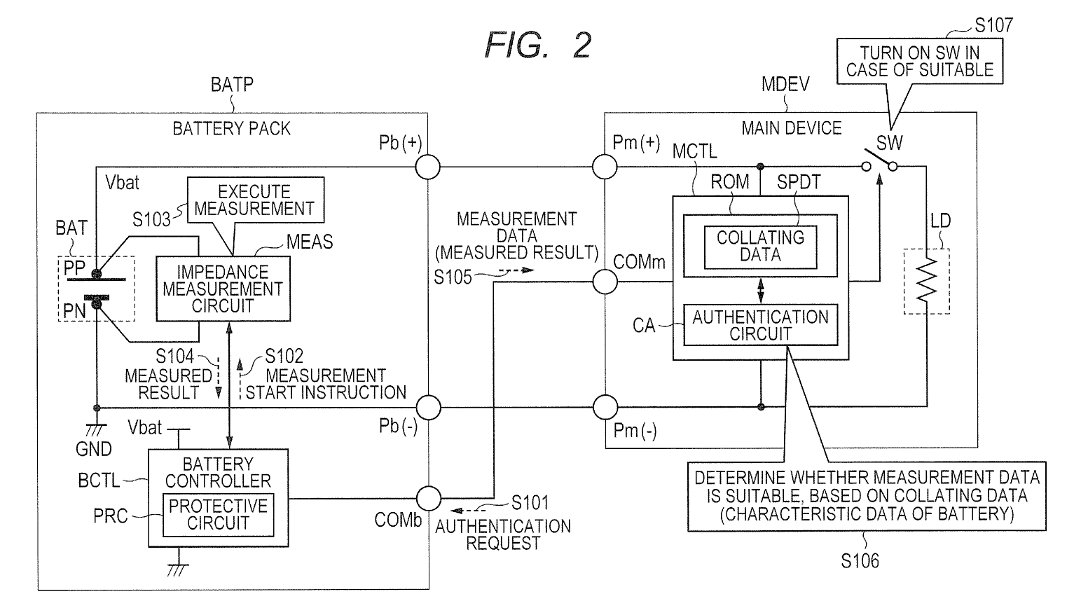

FIG. 2 is an explanatory diagram illustrating a schematic operational example of the main part in the battery driven system of FIG. 1. In FIG. 2, the authentication circuit CA of the main device MDEV transmits an authentication request from the communication terminal COMm, in a state where the switch SW is controlled to be OFF (Step S101). The battery controller BCTL of the battery pack BATP issues a measurement start instruction to the impedance measurement circuit MEAS, in response to the authentication request received by the communication terminal COMb (Step S102).

The impedance measurement circuit MEAS measures the impedance of the secondary battery BAT in accordance with the measurement start instruction (Step S103), and transmits the measured result to the battery controller BCTL (Step S104). The battery controller BCTL performs a predetermined measurement result process (for example, calculation of parameters to be required) based on the measured result, and transmits measurement data as the processed result from the communication terminal COMb (Step S105).

The authentication circuit CA receives the measurement data by the communication terminal COMm, and determines whether the measurement data is suitable based on the collating data SPDT (Step S106). Specifically, the collating data SPDT includes parameters which are identified in advance in the design stage, in association with the impedance of the secondary battery BAT, for example. The authentication circuit CA determines whether the parameters acquired based on the measured result of the impedance measurement circuit MEAS are included in a predetermined range (for example, the variation range corresponding to the production tolerance, the measurement error, and the variation with time), based on the parameters included in the collating data SPDT. When the parameters are included in the predetermined range, the authentication circuit CA determines that the measurement data (in other words, the secondary battery BAT) is suitable, whereas, when the parameters are not included therein, it is not suitable.

After this, when determined that it is suitable, the authentication circuit CA controls the switch SW to be turned on, to supply power to the load unit LD (Step S107). When determined that it is not suitable, the authentication circuit CA controls the switch SW to be off, not to supply power to the load unit LD.

### <Main Effect of Embodiment 1>

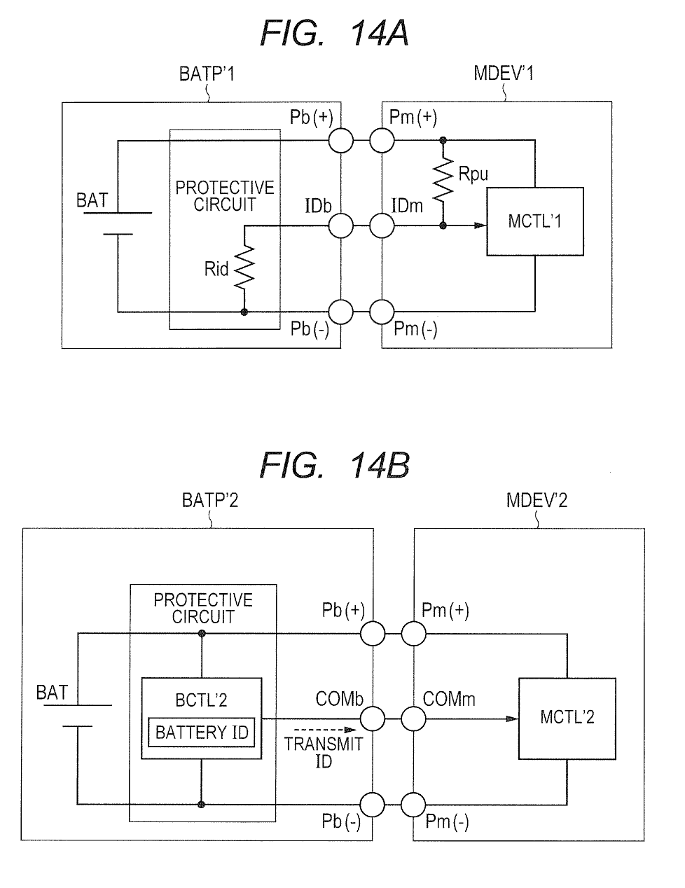

FIG. 14A and FIG. 14B are schematic diagrams illustrating a configuration example of the main part in the battery driven system which has been examined as a comparative example of the present invention. In FIG. 14A, a battery pack BATP′1 includes an ID setting terminal IDb and an ID setting resistance Rid coupled to this terminal, in addition to the secondary battery BAT. A main device MDEV′1 includes an ID setting terminal IDm and a pull-up resistance Rpu coupled to this terminal. Amain controller MCTL′1 of the main device MDEV′1 detects a division ratio of the pull-up resistance Rpu and the ID setting resistance Rid through the ID setting terminal IDm, thereby reading a resistance value of the ID setting resistance Rid. The resistance value of the ID setting resistance Rid differs between the manufacturers of the battery pack. The main controller MCTL′1 determines whether the battery pack BATP′1 is a regular product or a counterfeit product, based on the difference of this resistance value.

In FIG. 14B, a battery pack BATP′2 includes the communication terminal COMb and a battery controller BCTL′2 coupled to this terminal, in addition to the secondary battery BAT. The main device MDEV′2 includes the communication terminal COMm and the main controller MCTL′2 coupled to this terminal. The battery controller BCTL′2 holds battery IDs representing the type names or types in advance, and transmits the battery ID from the communication terminal COMb. The main controller MCTL′2 identifies the battery ID received by the communication terminal COMm, thereby determining whether the battery pack BATP′2 is a regular product or a counterfeit product. For this communication, encryption communication may be used for further ensuring the security.

In this configuration, for example, when only the secondary battery BAT is replaced by a poor-quality product, it is difficult to guarantee the safety of the secondary battery BAT. In the system of this embodiment 1, the impedance characteristic of the secondary battery BAT is measured in fact, and a determination is made as to whether the secondary battery BAT is a poor-quality product based on the measured result. Thus, it is possible to absolutely ensure the safety of the secondary battery BAT. That is, using the system of the embodiment 1, even if the battery pack is not a regular product, it may be determined that the battery pack is suitable, as long as the impedance characteristic of the secondary battery BAT satisfies a preset condition, in some case. Even in this case, it is advantageous that the safety of the secondary battery BAT is guaranteed.

That is, particularly the lithium ion battery is high in energy density, and uses an organic solvent, thus resulting in a malfunction and an increase in the risk of danger in case of accidental event. The market scale of the lithium ion battery is large, and the poor-quality products thereof exist with an increased possibility. Thus, if this accidental event once occurs, the regular manufacturers may undesirably and seriously be damaged due to the large scale of the market, regardless of whether it is a regular product or a counterfeit product. Using the system of this embodiment 1, it is possible to reduce the possibility of the occurrence of the damage.

In the system of FIG. 14A, by making a counterfeit ID setting resistance Rid, the counterfeit product of the battery pack may easily be manufactured. The ID setting terminals IDb and IDm as dedicated terminals are necessary, thus causing an increase in the number of terminals. Using the system of the embodiment 1, because the originally included communication terminal can be used, the dedicated terminals are not necessary. In addition, the counterfeit products cannot easily be made, as compared with the case of using the ID setting resistance Rid.

In the system of FIG. 14B, for example, it is possible to realize high confidentiality by using the encryption communication. Thus, it is advantageous from the point of view of authenticating the battery pack, instead of authenticating the secondary battery BAT, like the system of the embodiment 1. Note that the encryption communication is correlated between the confidentiality and the cost. That is, as the confidentiality is increased, the cost increases more and more. In addition, the authentication process may undesirably be complicated as compared with the system of the embodiment 1. However, for example, in consideration of the possibility that the measurement data itself is forged, encryption communication may be used in the communication in Steps S101 and S105 of FIG. 2.

### Embodiment 2

### <Details of Impedance Measurement Method>

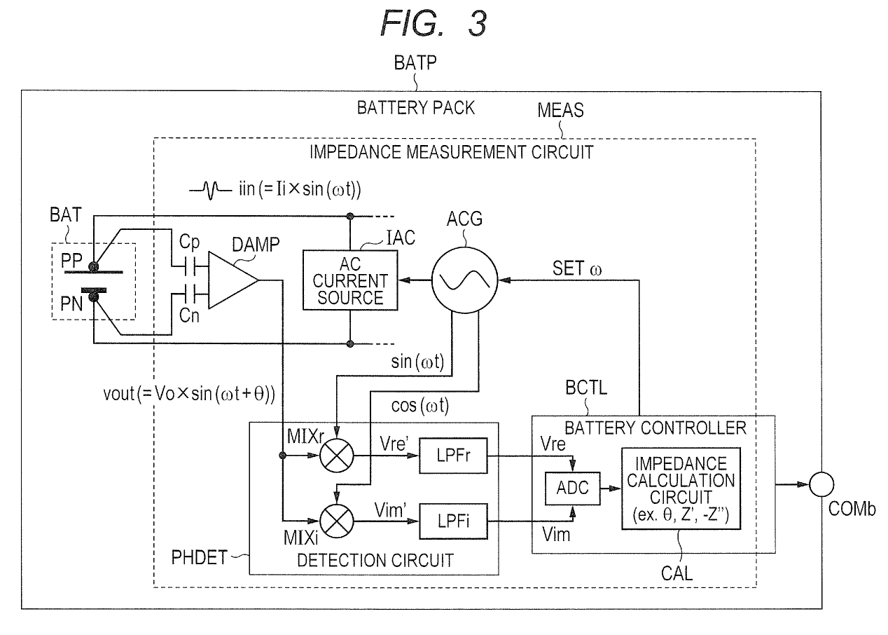

FIG. 3 is a circuitry diagram illustrating a configuration example of the surroundings of an impedance measurement circuit in the battery pack of FIG. 1, in a battery driven system of an embodiment 2 of the present invention. The impedance measurement circuit MEAS illustrated in FIG. 3 includes an AC signal source ACG, an AC current source IAC, DC cut capacitors Cp and Cn, a differential amplifier circuit DAMP, and a detector circuit PHDET. In this case, the impedance measurement circuit MEAS is configured with a part of the battery controller BCTL. This part of the battery controller includes an analog/digital converter ADC and an impedance calculation circuit CAL.

The AC signal source ACG generates a plurality of AC signals with different frequencies (angular frequencies ω), in response to an instruction from the battery controller BCTL. The AC current source IAC receives an AC signal (sin (ω·t)) from the AC signal source ACG, and generates an AC current signal iin (=Ii×sin (ω·t)) having the same phase as that of the AC signal. The AC current source IAC applies the AC current signal iin to the secondary battery BAT in a manner that it is embedded in the DC current of the secondary battery BAT. The differential amplifier circuit DAMP receives a voltage between the electrodes PP and PN of the secondary battery BAT, to be generated in accordance with the AC signal iin, through the DC cut capacitors Cp and Cn. Then, the circuit differentially amplifies it, thereby outputting an AC voltage signal vout (=Vo×sin (ω·t+θ)) with only an AC component.

The detection circuit PHDET includes multipliers MIXr and MIXi, and low pass filter circuits LPFr and LPFi. It receives the AC voltage signal vout from the secondary battery BAT through the differential amplifier circuit DAMP, and detects a phase difference θ between the AC current signal iin and the AC voltage signal vout. Specifically, the multiplier MIXr multiplies the AC voltage signal vout by a reference voltage signal (sin (ω·t)), transmitted from the AC signal source ACG and having the same phase as that of the AC current signal iin. Then, it outputs the multiplied result through the low pass filter circuit LPFr. This results in obtaining a real part Vre of the AC voltage signal vout, as an output voltage Vre of the low pass filter circuit LPFr.

The multiplier MIXi multiplies the AC voltage signal vout by a reference voltage signal (cos (ω·t)), transmitted from the AC signal source ACG and having a phase orthogonal to that of the AC current signal iin. Then, it outputs the multiplied result through the low pass filter LPFi. This results in obtaining an imaginary part Vim of the AC voltage signal vout, as an output voltage Vim of the low pass filter circuit LPFi.

More specifically, the impedance Z of the secondary battery BAT is Z=vout/iin, and is (Vo/Ii)□θ in the vector display. A real part Z′ and an imaginary part Z″ of the impedance Z are expressed respectively by equations (1) and (2). In the equation (1) and (2), a current value of Ii is set in advance.

Z′=(Vo/Ii)×cos θ (1)

Z″=(Vo/Ii)×sin θ (2)

The multiplier MIXr multiplies, as expressed by an equation (3), the AC voltage signal vout by the reference voltage signal (sin (ω·t)). The low pass filter circuit LPFr filters this multiplied result Vre′, thereby detecting the real part Vre expressed by an equation (4). Like an equation (5), the multiplier MIXi multiplies the AC voltage signal vout by the reference voltage signal (cos (ω·t)). The low pass filter circuit LPFi filters this multiplied result Vim′, thereby detecting the imaginary part Vim expressed by an equation (6).

Vre′=Vo×sin(ω·t+θ)×sin(ω·t) (3)

Vre=(Vo/2)×cos θ (4)

Vim′=Vo×sin(ω·t+θ)×cos(ω·t) (5)

Vim=(Vo/2)×sin θ (6)

The relationship of the real part Vre and the imaginary part Vim is expressed by equations (7) and (8). As a result, the magnitude Vo of the AC voltage signal vout is expressed by an equation (9). The phase difference θ between the AC current signal iin and the AC voltage signal vout is expressed by an equation (10).

Vre²+Vim²=(Vo/2)² (7)

Vim/Vre=sin θ/cos θ (8)

Vo=2×√(Vre²+Vim²) (9)

θ=tan⁻¹(Vim/Vre) (10)

In this manner, if Vo and θ are derived, the real part Z′ and the imaginary part Z″ of the impedance Z can also be derived, by the equations (1) and (2). The analog/digital converter ADC of the battery controller BCTL converts the real part Vre and the imaginary part Vim from the low pass filter circuits LPFr and LPFi into digital values. The impedance calculation circuit CAL of the battery controller BCTL performs calculations of the equations (9), (10), (1), and (2) using the digital values, thereby deriving the phase difference e, the real part Z′, and the imaginary part Z″.

The measurement method of the impedance Z is not necessarily limited to the system illustrated in FIG. 3, and any other systems are applicable. For example, it is possible to use a measurement method for measuring an AC current signal by applying an AC voltage signal. In addition, those applicable known methods maybe an automatic balance bridge method, abridge method, and a resonance method. The automatic balance bridge method is a method for measuring the impedance of a device under test (called a DUT) using a vector voltage ratio of the DUT to the range resistance and a resistance value of the range resistance, by flowing the same current as that to the DUT to the range resistance. The bridge method is a method for measuring the impedance of the DUT by searching for the balance condition of a Wheatstone bridge circuit including the DUT. The resonance method is a method for measuring the impedance of the DUT by searching for the resonance condition using a known reactance element.

### <Details of Authentication Method>

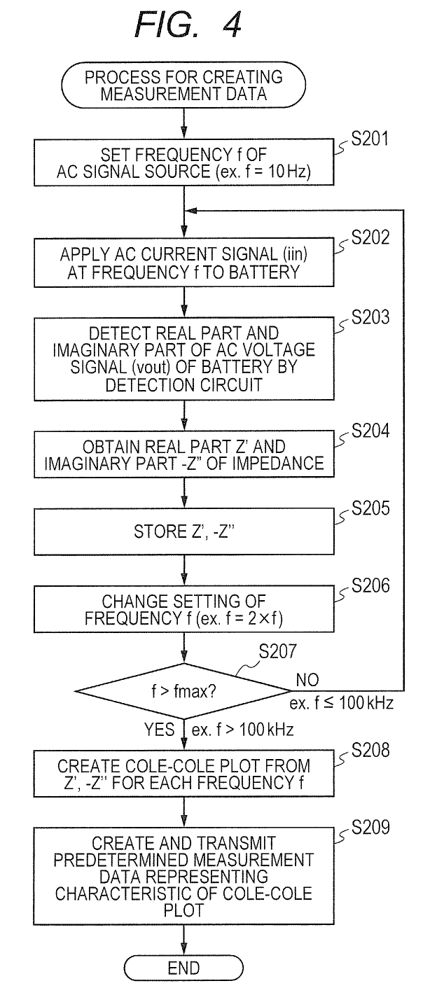

FIG. 4 is a flow diagram showing an example of process contents when the battery pack of FIG. 1 creates measurement data, in the battery driven system according to the embodiment 2 of the present invention. The battery controller BCTL controls the impedance measurement circuit MEAS illustrated in FIG. 3 to perform impedance measurement, in response to an authentication request from the main device MDEV. At this time, the battery controller BCTL sets a frequency f (angular frequency ω=2πf) of an AC signal for the AC signal source ACG (Step S201). Though not particularly limited, the frequency f is, for example, 10 Hz.

The AC signal source ACG generates an AC signal of the set frequency f now. Then, the AC current source IAC generates an AC current signal iin of the frequency f, and applies it to the secondary battery BAT (Step S202). As explained in FIG. 3, the detection circuit PHDET receives the AC voltage signal vout corresponding to the AC current signal iin, and detects its real part Vre and an imaginary part Vim (Step S203). In other words, the detection circuit PHDET detects a phase difference (a phase difference of the impedance Z) θ between the AC current signal iin and the AC voltage signal vout and also the absolute value (Vo) of the AC voltage signal vout, based on the real part Vre and the imaginary part Vim.

As explained in FIG. 3, the battery controller BCTL (specifically, the impedance calculation circuit CAL) calculates the real part Z′ and the imaginary part (−Z″) of the impedance Z (Step S204), based on the detected result. The imaginary part (−Z″) is a capacitive component in the case of the secondary battery BAT, and thus is negative. After the battery controller BCTL stores the real part Z′ and the imaginary part (−Z″) in the internal memory circuit (Step S205), it instructs to change the setting of the frequency f for the AC signal source ACG (Step S206). Though not particularly limited, the battery controller BCTL instructs to set the frequency f at twice the set frequency.

The battery controller BCTL sequentially instructs to change the setting of the frequency f for the AC signal source ACG, until the frequency f exceeds the preset maximum frequency fmax. Then, the procedures of Steps S202 to S206 are repeatedly executed (Step S207). Though not particularly limited, the maximum frequency fmax is 100 kHz.

By executing the above procedures, the impedance measurement circuit MEAS can measure the real part Z′ and the imaginary part (−Z″) of the impedance Z of the secondary battery BAT, for each of a plurality of AC signals having different frequencies f. As a result, the battery controller BCTL can create a Cole-Cole plot, in the stage where the frequency f in Step S207 exceeds the maximum frequency fmax (Step S208). The battery controller BCTL refers to the created Cole-Cole plot, creates predetermined measurement data (described later) representing the characteristic, and transmits it from the communication terminal COMb (Step S209).

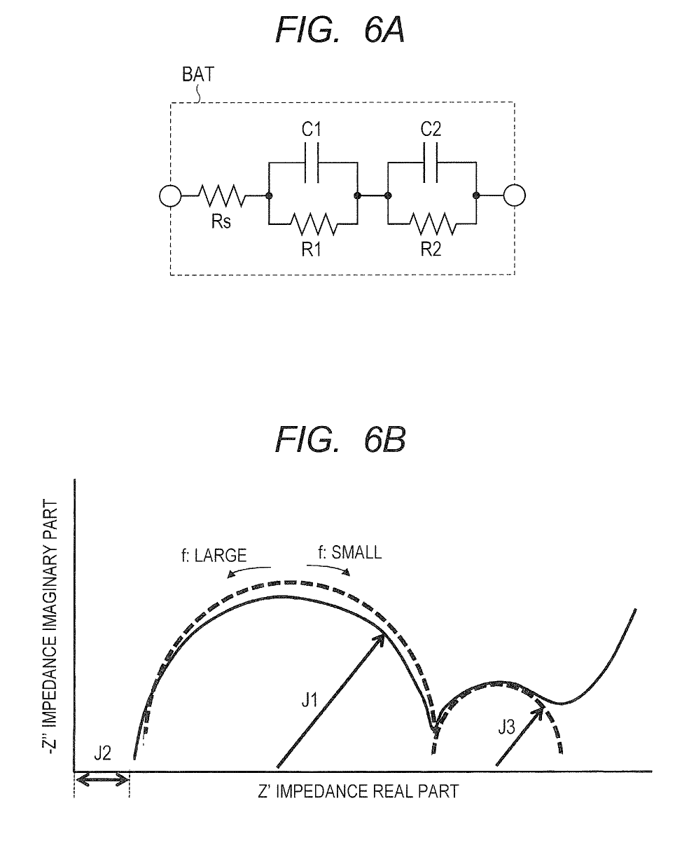

FIG. 6A is a circuitry diagram illustrating an example of an equivalent circuit of the secondary battery, in the battery pack of FIG. 3, and FIG. 6B is a characteristic diagram illustrating an example of the characteristic of the Cole-Cole plot. As illustrated in FIG. 6A, the secondary battery BAT can be represented in the form of an equivalent circuit. This equivalent circuit includes, for example, a resistance Rs, a parallel circuit of a resistance R1 and a capacitor C1, and a parallel circuit of a resistance R2 and a capacitor C2, which are serially coupled. The resistance Rs mainly represents an internal resistance of the secondary battery BAT. The resistance R1 and the capacitor C1 mainly represent the characteristics of the positive electrode PP and the negative electrode PN. The resistance R2 and the capacitor C2 mainly represent the characteristic of an electrolytic solution.

As illustrated in FIG. 6B, the Cole-Cole plot plots the frequency dependency, when the horizontal axis shows the real part Z′ of the impedance Z, and the vertical axis shows the imaginary part (−Z″) of the impedance Z. For example, when the frequency f is high, the capacitors C1 and C2 are in a short-circuit state. In this frequency range, as illustrated with a characteristic J2, the impedance Z is set mainly by the resistance Rs, and is derived by the real part.

When the frequency f is decreased, the capacitor C2 with a capacity value larger than that of the capacitor C1 is in a short-circuit state. The impedance Z is set mainly by the capacitor C1 and the resistance R1, in addition to the resistance Rs. In this frequency range, the characteristic of the impedance Z is derived in a semicircular form, based on a combination of the real part and the imaginary part. In FIG. 6B, a radius value of this semicircle is identified as the characteristic J1. If the frequency f is further decreased, the impedance Z is set by the capacitor C2 and the resistance R2, in addition to the resistance Rs, the capacitor C1, and the resistance R1. Even in this frequency range, the characteristic of the impedance Z can be derived in a semicircular form. In FIG. 6B, a radius value of this semicircle is identified as a characteristic J3.

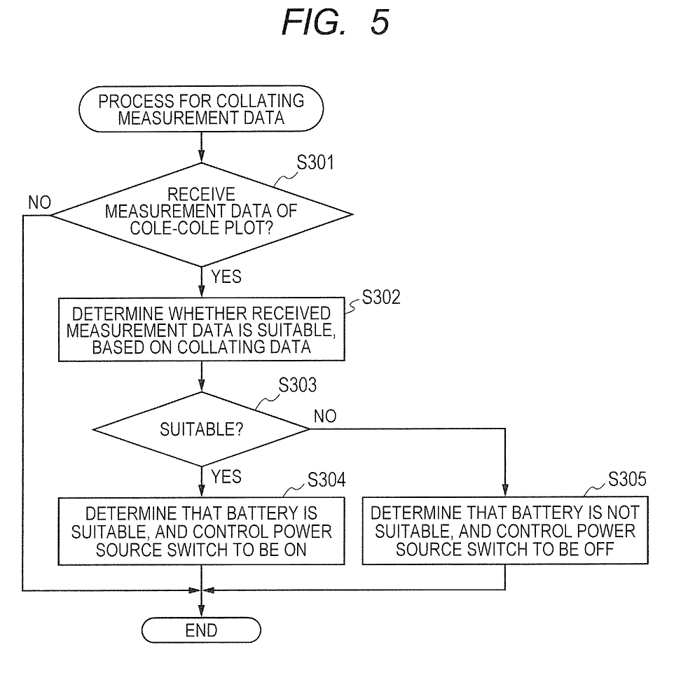

FIG. 5 is a flow diagram showing an example of process contents when an authentication circuit of the main device of FIG. 1 collates the measurement data, in the battery driven system according to the embodiment 2 of the present invention. In FIG. 5, when measurement data of the Cole-Cole plot is received from the battery pack BATP (Step S301), the authentication circuit CA determines whether the measurement data is suitable based on the collating data SPDT (Steps S302, 303).

The collating data SPDT is data of the Cole-Cole plot which is obtained in the design stage, and is set based on at least one of or a combination of, for example, the radius value of the semicircle identified by the characteristic J1 of FIG. 6B, the resistance value identified by the characteristic J2, and the radius value of the semicircle identified by the characteristic J3. In Step S209 of FIG. 4, the battery controller BCTL refers to the Cole-Cole plot as the measured result, and creates the set radius value or the resistance value corresponding to the characteristic, as measurement data.

When the collating data SPDT represents the radius value of the characteristic J1 or the characteristic J3, the authentication circuit CA determines whether the measurement data is suitable, in accordance with whether the radius value included in the measurement data is within a predetermined range based on a corresponding radius value as a reference included in the collating data SPDT. Similarly, when the collating data SPDT is the resistance value of the characteristic J2, the authentication circuit CA determines whether the measurement data is suitable, in accordance with whether the resistance value included in the measurement data is within a predetermined range based on a corresponding resistance value as a reference included in the collating data.

When the measurement data is suitable (that is, within the predetermined range), the authentication circuit CA determines that the secondary battery BAT is suitable, and controls the switch SW to be turned on (Step S304). When the measurement data is not suitable (that is, not within the predetermined range), the authentication circuit CA determines that the secondary battery BAT is not suitable, and controls the switch SW to be turned off (Step S305).

### <Determination Condition at the Time of Authentication>

For Steps S302 and S303 of FIG. 5, descriptions will now specifically be made to a determination condition at the time of determining whether the measurement data is suitable. The predetermined range is preferably set as small as possible at the determination as to whether the above-described measurement data is suitable, in consideration of the variation width corresponding to the production tolerance, the measurement error, or the variation with time. Though not particularly limited, the predetermined range is ±30%, when the determination is made using the radius value of the characteristic J1. When the determination is made using the resistance value of the characteristic J2, it is considered that the variation width is lower than that of the characteristic J1, and thus the range is ±20%. When the determination is made using the radius value of the characteristic J3, it is considered that the variation width is greater than that of the characteristic J1, and thus the range is ±50%.

The characteristic J1 mainly changes in accordance with the used metal or the electrode composition of the electrode materials for the secondary battery BAT. In the system using the secondary battery BAT, the battery electrode materials are selected, in accordance with the current for use, the voltage range, and the usage environmental condition. The output load condition, the heat generation characteristic, and the safety of the secondary battery BAT remarkably change, in accordance with the used metal or the electrode composition used for the electrode materials. Thus, if an inappropriate electrode material is used, a load current necessary for the system cannot be obtained. This may possibly result in a malfunction that the system does not operate, heat generation from the electrode during use, and firing and exploding of the secondary battery BAT.

A determination is now made as to whether the radius value of the characteristic J1 is within a predetermined range (for example, ±30%), based on the radius value, set as a reference in the design stage. This predetermined range particularly depends on the degradation (change) of the electrode due to repetitive charging/discharging of the secondary battery BAT. This predetermined range changes in accordance with the electrode material or the condition of the system operation. Thus, it is not limited to ±30%, and any values are set appropriately based on the conditions.

The characteristic J2 changes mainly in accordance with the structure (battery can, material/structure of a lead wire from the electrode, and structure of a seal part of the battery) of the secondary battery BAT. Unlike the characteristics J1 and J3, the characteristic J2 is basically the resistance characteristic of only the real part, because it depends on the metal resistance or the cross-sectional area/length of the structural materials. In the system using the secondary battery BAT, a suitable battery structure and structural materials are selected in accordance with the current for use, the voltage range, and the usage environmental condition. The output load condition, the heat generation characteristic, or the safety depends on the structural materials to be used. The characteristic J2 is in relation to the mechanical characteristic, for example, the vibration/impact resistance due to the usage environmental condition. Thus, if an inappropriate structure is adopted, a malfunction may possibly occur in the functions or safety.

Now, a determination is made as to whether the resistance value of the characteristic J2 is within a predetermined range (for example, ±20%) based on the resistance value as a reference set in the design stage. This predetermined range depends on the structure of the above-described secondary battery BAT, resulting in a smaller variation width than the characteristic J1. Note that this predetermined range changes in accordance with the structure or used metal. Thus, it is not limited to ±20%, and any values are set appropriately based on the conditions.

The characteristic J3 changes mainly by the composition or additives of the electrolytic solution of the battery. Like the case of the characteristic J1, the electrolytic solution is selected appropriately in accordance with the system conditions. Use of an inappropriate electrolytic solution may cause a malfunction in the functions or the safety. Particularly, the electrolytic solution remarkably changes in accordance with the degradation, thus greatly influencing the life of the system.

By determining as to whether the radius value of the characteristic J3 is within a predetermined range (for example, ±50%) based on the radius value as a reference set in the design stage, it is possible to determine the suitability, including the degradation level of the secondary battery BAT. This predetermined range more changes in accordance with the actual use (charging/discharging cycles) than the characteristic J1. Thus, it is set to a larger value than the characteristic J1. Note that this predetermined range changes in accordance with the composition, the additives, or the system condition. Thus, it is not limited to ±50%, and any values are set appropriately based on these.

The characteristics J1, J2, and J3 for use in the determinations have respective priority levels sequentially high in this order. Thus, the determination conditions include, for example, the characteristic J1, preferably include the characteristic J2, and more preferably include the characteristic J3. The more the determination conditions, it is possible to determine the suitability of the secondary battery BAT more precisely. In other words, it is possible to guarantee securely the safety of the secondary battery BAT. On the contrary, the more the determination conditions, the time and cost increase for executing the process of FIG. 4 and the process of FIG. 5. For example, at the time of determination of the characteristic J1, it is possible to set the variation range of the frequency in FIG. 4 in the range obtaining this characteristic J1. The determination conditions are appropriately set in consideration of this trade-off.

The characteristic J1 has the largest effect (particularly, the effect on the electric characteristic) on the system, in terms of its properties. Further, the characteristic J1 has the maximum percentage among the elements of the Cole-Cole plot, and is a characteristic for easily identifying the secondary battery BAT. From this point of view, the characteristic J1 has the highest property level. In combination with the characteristic J2, it is possible to determine whether it is suitable, including the structure of the secondary battery BAT or the mechanical characteristic of the system. Further, in combination with the characteristic J3, it is possible to determine whether it is suitable, including the degradation level of the secondary battery BAT. For example, the degradation level may remarkably be decreased in the poor-quality secondary battery BAT.

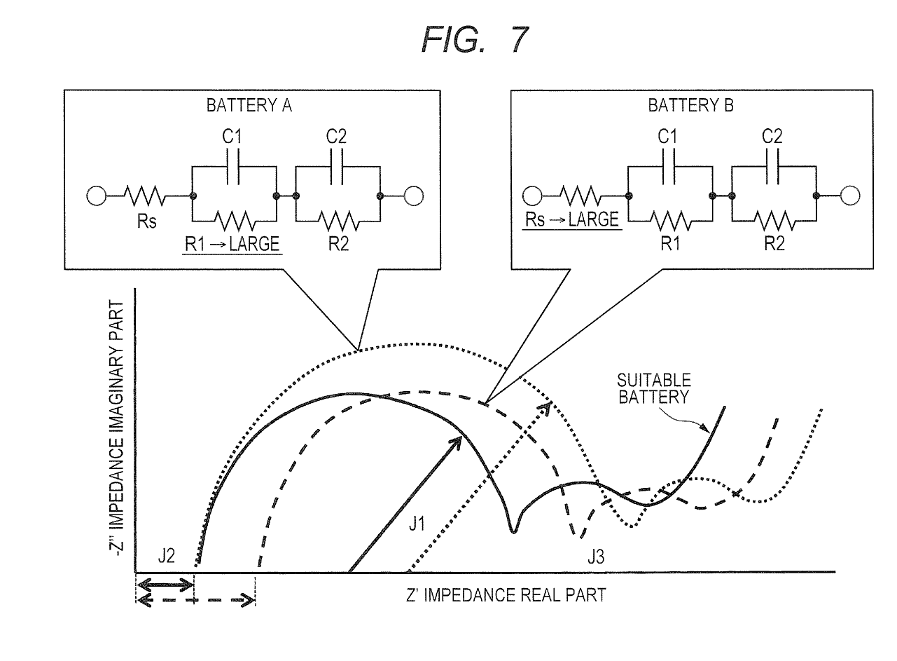

FIG. 7 is a diagram illustrating a characteristic example of the Cole-Cole plot regarding a secondary battery which is determined as “not suitable”, in the flow of FIG. 5. In FIG. 7, the battery A is formed with an electrode material which is not suitable to the output load characteristic of the system, and the overall impedance (particularly the resistance R1) is remarkable. As a result, in the battery A, the radius value of the characteristic J1 is too large, and determined as “not suitable”. On the other hand, in the battery B, for example, the lead wire of the electrode has a thin structure, or a current limiting element, such as PTC (Positive Temperature Coefficient) is provided, and the resistance Rs is high. As a result, in the battery B, the resistance value of the characteristic J2 is too large, and it is determined as “not suitable”.

### <Main Effect of Embodiment 2>

Accordingly, with the battery driven system of the embodiment 2, using the Cole-Cole plot in addition to various effects described in the embodiment 1, it is possible to precisely verify the suitability of the secondary battery BAT, and to securely guarantee the safety of the secondary battery BAT. Note, in this case, the battery controller BCTL calculates and transmits the values of the characteristics J1 to J3 (the radius values or the resistance values), based on the measured results of the impedance at the frequencies. However, it may simply transmit the measured results, while the main controller MCTL calculates the characteristics J1 to J3. In this case, the communication traffic of the communication terminals COMb and COMm increases. From this point of view, the battery controller BCTL preferably calculates the values of the characteristics J1 to J3.

### Embodiment 3

### <Details of Impedance Measurement Method (Modification 1)>

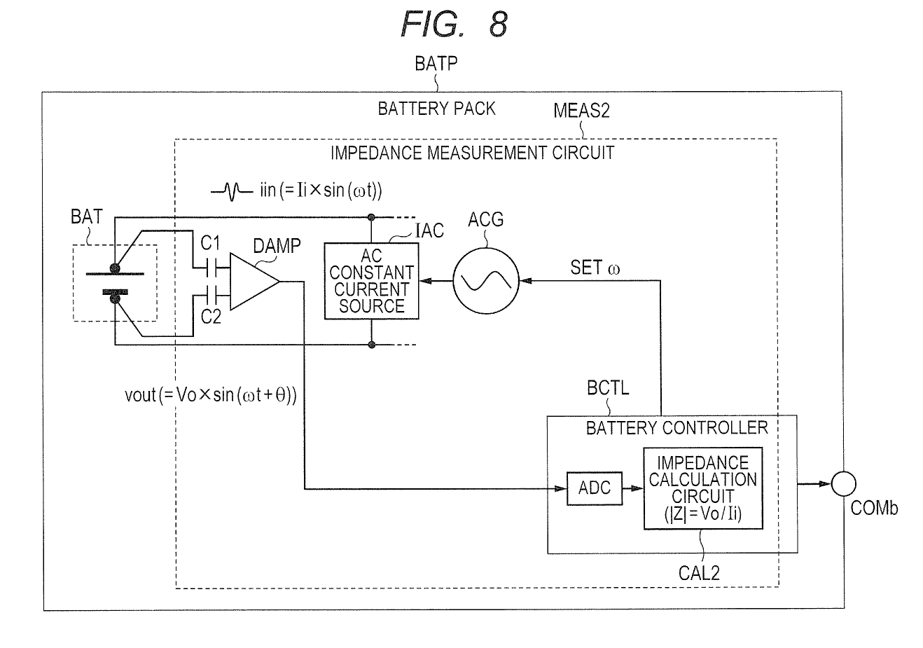

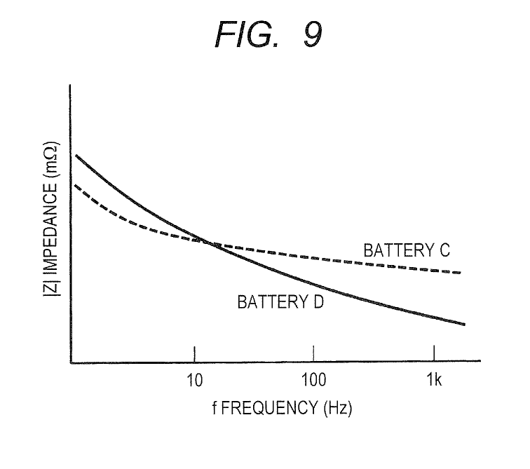

FIG. 8 is a circuitry diagram illustrating a configuration example of the surroundings of an impedance measurement circuit in the battery pack of FIG. 1, in a battery driven system according to an embodiment 3 of the present invention. FIG. 9 is a characteristic diagram illustrating an example of a measured result in the impedance measurement circuit of FIG. 8. An impedance measurement circuit MEAS 2 illustrated in FIG. 8 is configured with the impedance measurement circuit MEAS illustrated in FIG. 3, excluding the detection circuit PHDET. The battery controller BCTL includes an impedance calculation circuit CAL2 performing calculations different from those of FIG. 3, as apart of the impedance measurement circuit MEAS2.

The analog/digital converter ADC of the battery controller BCTL converts the AC voltage signal vout (=Vo×sin (ω·t+θ)) in association with each of the frequencies, from the same differential amplifier circuit DAMP as that of FIG. 3, into a digital value. The impedance calculation circuit CAL2 calculates the absolute value |Z| (=Vo/Ii) of the impedance Z of the secondary battery BAT in association each of the frequencies, using the digital value and a preset magnitude Ii of the AC current signal iin.

By performing this measurement, the impedance measurement circuit MEAS2 can measure the absolute value |Z| of the impedance Z of the secondary battery BAT, for a plurality of signals with different frequencies. This results in obtaining the frequency dependencies of the absolute values |Z| of the impedance Z, as illustrated in FIG. 9. The frequency dependency differs between the batteries, as illustrated with batteries C and D illustrated in FIG. 9. Thus, it is possible to determine the suitability of the secondary battery BAT, by holding data representing the frequency dependencies, as the collating data SPDT of FIG. 2.

Specifically, for example, there is provided a method for controlling the authentication circuit CA to perform the collation, by the impedance measurement circuit MEAS2 measuring the absolute value |Z| of the impedance Z at two or more frequencies, and transmitting the measured result from the communication terminal COMb. In this case, the authentication circuit CA determines the suitability based on a determination as to whether the received measured results are included in a predetermined range, based on the absolute value |Z| of the impedance Z included in the collating data SPDT, as a reference at a corresponding frequency.

To precisely determine the suitability, it is preferred that the number of frequencies to be measured is large. This causes an increase in the communication traffic of the communication terminals COMb and COMm. The impedance measurement circuit MEAS2 may approximate, for example, the measured frequency dependency by a preset approximation function, and transmit coefficients of the approximation function from the communication terminal COMb. In this case, the authentication circuit CA determines the suitability based on a determination as to whether the received coefficients are included in a predetermined range, based on the corresponding coefficient included in the collating data SPDT, as a reference.

### <Details of Impedance Measurement Method (Modification Example 2) >

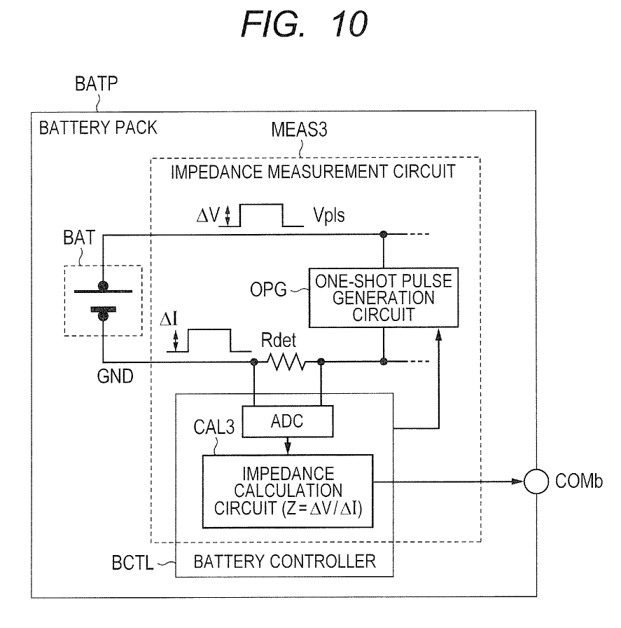

FIG. 10 is a circuitry diagram illustrating another configuration example of the surroundings of the impedance measurement circuit in the battery pack of FIG. 1, in the battery driven system according to the embodiment of the present invention. The impedance measurement circuit MEAS3 illustrated in FIG. 10 includes a one-shot pulse generation circuit OPG, a current detection resistance Rdet, and an analog/digital converter ADC and an impedance calculation circuit CAL3 in the battery controller BCTL.

The one-shot pulse generation circuit OPG is coupled to the secondary battery BAT, and applies a one-shot pulse voltage signal Vpls with a voltage amplitude ΔV to the secondary battery BAT. The current detection resistance Rdet is inserted in series into the path of the reference source voltage GND. A provided part (for example, an overcurrent detection circuit) of, for example, the protective circuit of the battery pack BATP may be used as the current detection resistance Rdet.

In response to the one-shot pulse generation signal Vpls, the secondary battery BAT outputs a current signal with a current amplitude ΔI corresponding to the current resistance value. The analog/digital converter ADC measures this current amplitude ΔI using the current detection resistance Rdet. The impedance calculation circuit CAL3 obtains the DC impedance of the secondary battery BAT from ΔV/ΔI, and transmits it from the communication terminal COMb, for the authentication circuit CAT to collate it.

### <Main Effect of Embodiment 3>

Accordingly, using the battery driven system of the embodiment 3, it is possible to determine the suitability with a simpler system than that of the embodiment 2, in addition that the same effects as that of the embodiment 1 can be attained. Specifically, when the system of FIG. 8 is used, the configuration of the impedance measurement circuit MEAS2 can be more simplified as compared to the system of FIG. 3, and the number of frequencies to be measured may possibly be reduced. When the system of FIG. 10 is used, the configuration of the impedance measurement circuit MEAS3 can be simplified as compared to that of FIG. 3, and there is no need to control the frequency. From the point of view of precise determination of the suitability (in other words, securely guarantee the safety of the secondary battery BAT), the system of FIG. 3 is most preferable, the system of FIG. 8 is the second most preferable, and the system of FIG. 10 is the third most preferable.

In the configuration of FIG. 8, sampling and holding of the output voltage signal vout are performed directly by the analog/digital converter ADC, thereby detecting its magnitude Vi. However, for example, a peak hold circuit using a forward diode may be inserted between the differential amplifier circuit DAMP and the analog/digital converter ADC. Needless to say, the frequency dependency of the absolute value |Z| of the impedance Z may possibly be measured by the configuration of FIG. 3.

### Embodiment 4

### <Schematic Configuration of Battery Driven System (Modification)>

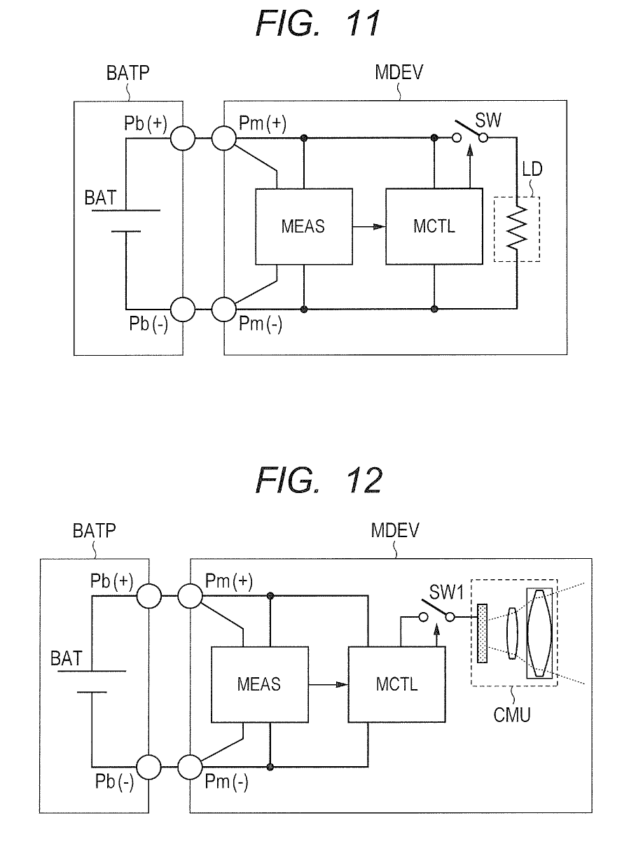

FIG. 11 is a schematic diagram illustrating a configuration example of the main part, in a battery driven system according to an embodiment 4 of the present invention. What differs from the configuration example of FIG. 1 is that, in the battery driven system illustrated in FIG. 11, the impedance measurement circuit MEAS is mounted on the main device MDEV, instead of the battery pack BATP. The impedance measurement circuit MEAS is coupled to the secondary battery BAT through the power source terminals Pm(+) and Pm(−), and measures the impedance of the secondary battery BAT.

The impedance measurement circuit MEAS specifically includes the configuration illustrated in FIG. 3, FIG. 8, or FIG. 10. As an example of the configuration of FIG. 3, for example, the AC signal source ACG, the AC current source IAC, the differential amplifier circuit DAMP, and the detection circuit PHDET can be formed with one semiconductor chip. The analog/digital converter ADC and the impedance calculation circuit CAL can be mounted on the main controller MCTL.

Using this configuration, also, the same effect as that of the embodiment 1 can be attained. Further, as compared with the case of the embodiment 1, the counterfeit product of the battery pack BATP can securely be excluded. In addition, the communication terminal COMb for the authentication of the battery is not necessary. Specifically, in the configuration of FIG. 1, for example, when the measurement data transmitted from the communication terminal COMb itself is forged, the counterfeit product of the battery pack BATP may not fearfully be excluded. Using the configuration example of FIG. 11, it is possible to avoid this situation, because the main device MDEV is one to create the measurement data. In the configuration example of FIG. 11, the measurement accuracy may fearfully be degraded, because the distance from the impedance measurement circuit MEAS to the secondary battery BAT is longer than that of the configuration example of FIG. 1. From this point of view, the configuration of FIG. 1 is more preferable.

### <Schematic Configuration of Battery Driven System (Application Example)>

FIG. 12 is a schematic diagram illustrating a configuration example of a battery driven system applying the system of FIG. 11. The battery driven system of FIG. 12 is, for example, a digital still camera, and includes an imaging unit CMU as a load unit (main unit) LD. The imaging unit CMU includes, for example, a CCD (CMOS) sensor or a lens.

The main controller MCTL controls a switch SW1 to be turned off, when the secondary battery BAT is not suitable. The switch SW1 is provided on the power source path or the signal path of the imaging unit CMU. From the point of view of eliminating the effect of the impedance of the imaging unit CMU when the impedance measurement circuit MEAS performs measurement, the switch SW1 is preferable provided at least on the power source path. In this manner, by controlling the switch SW1 to be turned off, it is possible to substantially invalidate the main function of the main device MDEV.

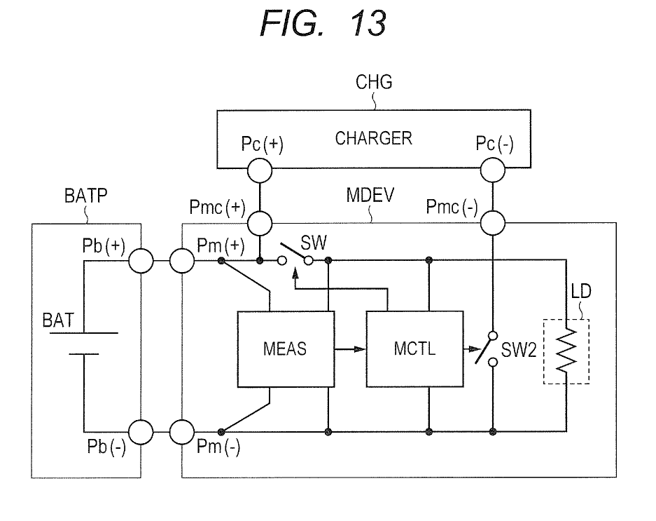

FIG. 13 is a schematic diagram illustrating another configuration example of a battery driven system applying the system of FIG. 11. The battery driven system of FIG. 13 includes a charger CHG in addition to the load unit LE, as the main unit. The main device MDEV includes charging terminals Pmc(+) and Pmc(−) respectively coupled to the power source terminals Pm(+) and Pm(−). The charger CHG includes charging terminals Pc(+) and Pc(−) respectively coupled to the charging terminals Pmc(+) and Pmc(−).

The main device MDEV includes a switch SW2 on the power source path of the charging device Pmc (−) and the power source terminal Pm (−). When the secondary battery BAT is not suitable, the main controller MCTL controls the switch SW2 to be turned on, thereby prohibiting the charge for the secondary battery BAT. For example, in the case of a poor-quality lithium ion secondary battery, the risk of danger increases at the charging. However, using this system, it is possible to increase the safety of the secondary battery BAT.

### <Main Effect of Embodiment 4>

Using the battery driven system of the embodiment 4, the same effects as those of the embodiment 1 can be attained. In addition, as compared with the case of the embodiment 1, it is possible to securely exclude the counterfeit product of the battery back BATP. The Impedance measurement circuit MEAS is not provided on the side of the battery pack BATP as the consumable supplies. Thus, it is possible reduce the total cost of the entire system.

Accordingly, the inventions of the present inventors have concretely been described based on the embodiments. However, the present invention is not limited to the embodiments, various changes may possibly be made without departing from the scope thereof. For example, the above-described embodiments have specifically been made for easy descriptions of the present invention, and made not to limit to any of those including the described configurations entirely. A part of the configuration of one embodiment may be replaced by a configuration of another embodiment. The configuration of one embodiment may be added to the configuration of another embodiment. A part of each embodiment may be added to, deleted from, or replaced by another configuration.

What is claimed is:

1. A battery driven system comprising:
a secondary battery which generates a power source;
a main unit to/from which the secondary battery is attachable/detachable;
a switch which is provided on a power source path or a signal path of the main unit;
an impedance measurement circuit which is coupled to the secondary battery and measures impedance of the secondary battery;
a memory circuit which holds a preset impedance characteristic of the secondary battery as collating data, and
an authentication circuit which determines whether the secondary battery is suitable, by comparing measurement data and the collating data based on a measured result of the impedance measurement circuit, and controls the switch to be turned off when it is not suitable.

2. The battery driven system according to claim 1,
wherein the collating data is data of a Cole-Cole plot, and
wherein the impedance measurement circuit includes an AC signal source generating a plurality of AC signals with frequencies different from each other, and measures a real part and an imaginary part of the impedance of the secondary battery in association with each of the AC signals.

3. The battery driven system according to claim 2,
wherein the collating data includes a radius value corresponding to a first range, in which the impedance characteristic is obtained based on a combination of the real part and the imaginary part in a semicircle form in the Cole-Cole plot, and
wherein the authentication circuit determines whether the secondary battery is suitable, in accordance with whether the radius value of the first range obtained using the measurement data is within a predetermined ranged based on the radius value included in the collating data as a reference.

4. The battery driven system according to claim 3,
wherein the collating data further includes a resistance value corresponding to a second range, in which the impedance characteristic can be obtained as a real part in the Cole-Cole plot, at a higher frequency than the first range, and
wherein the authentication circuit determines whether the secondary battery in accordance with the resistance value of the second range obtained from the measurement data is in a predetermined range based on the resistance value included in the collating data as a reference, in addition to the radius value of the first range.

5. The battery driven system according to claim 1,
wherein the collating data is data representing frequency dependency of an absolute value of the impedance of the secondary battery, and
wherein the impedance measurement circuit includes an AC signal source generating a plurality of AC signals with frequencies different from each other, and measures the absolute value of the impedance of the secondary battery in association with each of the AC signals.

6. The battery driven system according to claim 1,
wherein the battery driven system includes a battery pack and a main device to/from which the battery pack is attachable/detachable,
wherein the secondary battery and the impedance measurement circuit are mounted on the battery pack, and
wherein the memory circuit, the authentication circuit, and the main unit are mounted on the main device.

7. The battery driven system according to claim 1,
wherein the battery driven system includes a battery pack and a main device to/from which the battery pack is attachable/detachable,
wherein the secondary battery is mounted on the battery pack, and
wherein the impedance measurement circuit, the memory unit, the authentication circuit, and the main unit are mounted on the main device.

8. A battery pack comprising:
a secondary battery which generates a power source;
a power source terminal which is coupled to the secondary battery and attachable/detachable to/from a main device;
a communication terminal which communicates with the main device;
an impedance measurement circuit which is coupled to the secondary battery and measures impedance of the secondary battery; and
a battery controller which is coupled to the impedance measurement circuit and the communication terminal, and transmits measurement data based on a measured result of the impedance measurement circuit to the main device through the communication terminal.

9. The battery pack according to claim 8,
wherein the impedance measurement circuit includes an AC signal source generating a plurality of AC signals with frequencies different from each other, and measures a real part and an imaginary part of the impedance of the secondary battery in association with each of the AC signals.

10. The battery pack according to claim 9,
wherein the impedance measurement circuit includes
an AC current source which generates a plurality of AC current signals with frequencies different from each other, and
a detection circuit which receives AC voltage signals of the secondary battery in association respectively with the AC current signals, and detects a phase difference between each of the AC current signals and the AC voltage signals.

11. The battery pack according to claim 9,
wherein the battery controller creates a Cole-Cole plot based on the measured result of the impedance measurement circuit, obtains a radius value corresponding to a first range, in which an impedance characteristic is obtained based on a combination of the real part and the imaginary part in a semicircle form in the Cole-Cole plot, and transmits the radius value from the communication terminal.

12. The battery pack according to claim 11,
wherein the battery controller further obtains a resistance value corresponding to a second range, in which the impedance characteristic can be obtained as a real part in the Cole-Cole plot at a higher frequency than the first range, and transmits the resistance value in addition to the radius value from the communication terminal.

13. The battery pack according to claim 8,
wherein the impedance measurement circuit includes an AC signal source generating a plurality of AC signals with frequencies different from each other, and measures an absolute value of the impedance of the secondary battery in association with each of the AC signals.

14. A semiconductor device having one semiconductor chip or one package, comprising:
a power source terminal which is coupled to a secondary battery;
a communication terminal;
an impedance measurement circuit which measures impedance of the secondary battery through the power source terminal; and
a battery controller which is coupled to the impedance measurement circuit and the communication terminal, and transmits measurement data based on a measured result of the impedance measurement circuit from the communication terminal.

15. The semiconductor device according to claim 14,
wherein the impedance measurement circuit includes an AC signal source generating a plurality of AC signals with frequencies different from each other, and measures a real part and an imaginary part of impedance of the secondary battery in association with each of the AC signals.

16. The semiconductor device according to claim 15,
wherein the impedance measurement circuit includes
an AC current source which generates a plurality of AC current signals with frequencies different from each other, and
a detection circuit which receives AC voltage signals of the secondary battery in accordance respectively with the AC current signals, and detects a phase difference between each of the AC current signals and the AC voltage signals.

17. The semiconductor device according to claim 15,
wherein the battery controller creates a Cole-Cole plot based on a measured result of the impedance measurement circuit, obtains a radius value corresponding to a first range, in which an impedance characteristic is obtained based on a combination of the real part and the imaginary part in a semicircle form in the Cole-Cole plot, and transmits the radius value from the communication terminal.

18. The semiconductor device according to claim 17,
wherein the battery controller obtains a resistance value corresponding to a second range, in which the impedance characteristic can be obtained as a real part in the Cole-Cole plot at a higher frequency than the first range, and transmits the resistance value in addition to the radius value from the communication terminal.

19. The semiconductor device according to claim 14,
the impedance measurement circuit includes an AC signal source generating a plurality of AC signals with frequencies different from each other, and measures an absolute value of the impedance of the secondary battery in association with each of the AC signals.
